(19) United States
(12) Patent Application Publication
(10) Pub. No.: US 2002/0164540 A1
(43) Pub. Date: Nov. 7, 2002

(54) Chemical amplifying type positive resist composition

(76) Inventors: Junji Nakanishi, Kyoto-shi (JP); Katsuhiko Namba, Hirakata-shi (JP); Masumi Suetsugu, Toyonaka-shi (JP)

Correspondence Address: BIRCH STEWART KOLASCH & BIRCH, PO BOX 747, FALLS CHURCH, VA, 22040-0747, US

(21) Appl. No.: 10/084,182

(22) Filed: Feb. 28, 2002

(30) Foreign Application Priority Data
Mar. 5, 2001 (JP) 2001-059724

(51) Int. Cl. G03F 7/038

(52) U.S. Cl. 430/270.1; 430/296; 430/311; 430/905

(57) ABSTRACT

A chemical amplifying type positive resist composition comprising (A) a resin becoming alkali-soluble due to the action of an acid, (B) an acid generating agent, (C) a basic compound, and (D) a polyvalent carboxylic acid ester is provided, and it exhibits higher resolution without impairing resist performance such as application ability and sensitivity

### BACKGROUND OF THE INVENTION

The present invention relates to a resist composition suitable for lithography and the like, which acts by high energy radioactive ray such as far ultraviolet ray (including excimer laser and the like), electron beam, X ray or radiation light.

A lithography process using a resist composition has usually been adopted in the minute processing of a semiconductor. In the lithography, the resolution can be improved with a decrease in wavelength of exposure light in principle as expressed by the equation of Rayleigh's diffraction limit. A g-line with a wavelength of 436 nm, an i-line with a wavelength of 365 nm, and a KrF excimer laser with a wavelength of 248 nm have been adopted as exposure light sources for lithography used in the manufacture of a semiconductor. Thus, the wavelength has become shorter year by year. An ArF excimer laser having a wavelength of 193 nm and an electron beam are considered to be promising as a next-generation exposure light source

A lens used in an ArF excimer laser exposure machine or an KrF excimer laser exposure machine has a shorter lifetime as compared with lenses for conventional exposure light sources. Accordingly, the shorter time required for exposure to ArF or KrF excimer laser light is desirable. In a lithography process using an electron beam, sensitivity of resist largely affects the productivity. For this reason, it is necessary to enhance the sensitivity of a resist for ArF excimer laser, KrF excimer laser or an electron beam. Consequently, there has been used a so-called chemical amplifying type resist, which utilizes the catalytic action of an acid generated by exposure and contains a resin having a group cleavable by the acid.

An object of the present invention is to provide a positive resist composition exhibiting higher resolution without impairing resist performances such as sensitivity.

Viewing the above aspect, the present inventors have conducted extensive studies on chemical amplifying type positive resist compositions, and have found that a chemical amplifying type positive resist composition comprising four types of components represented by (A) a resin becoming alkali-soluble due to the action of an acid, (B) an acid a generating agent. (C) a basic compound, and (D) a polyvalent carboxylic acid ester can exhibit higher resolution without impairing resist performance such as application ability and sensitivity. The present invention has been attained based on this finding.

### SUMMARY OF THE INVENTION

The present invention provides a chemical amplifying type positive resist composition comprising (A) a resin becoming alkali-soluble due to the action of an acid, (B) an acid generating agent, (C) a basic compound, and (D) a polyvalent carboxylic acid ester.

### DESCRIPTION OF EMBODIMENTS

In the resist composition of the present invention, as (D) component, the polyvalent carboxylic acid ester, adipic acid esters, sebacic acid esters, azelaic acid esters, maleic acid esters, citric acid esters, phthalic acid esters and the like may be exemplified.

To be more specific, examples of such esters include di-n-hexyl adipate, n-hexyl-n-octyl adipate, di-n-octyl adipate, diisooctyl adipate, dicapryl adipate, di-2-ethylhexyl adipate, n-hexyl-n-decyl adipate, dulsononyl adipate, n-octyl-n-decyl adipate, isooctylisodecyl adipate, di-n-decyl adipate, diisodecyl adipate, dibutyl sebacate, di-2-ethylhexyl sebacate, di-2-ethylhexylazelate, di-2-ethylhexyl dodecanate, di-2-ethylhexyl maleate, O-acetyl tributyl citrate, dimethyl phthalate, diethyl phthalate, di-n-butylphthalate, di-n-octyl phthalate, di-2-ethylhexyl phthalate, diisooctyl phthalate, n-octyl-n-decyl phthalate, di-n-decyl phthalate, diisodecyl phthalate, di-n-dodecyl phthalate, diisotridecyl phthalate, dicyclohexyl phthalate, butylbenzil phthalate and di-2-ethylhexyl isophthalate.

Among the above, preferably used are di-n-hexyl adipate, n-hexyl-n-octyl adipate, di-2-ethylhexyl adipate, n-hexyl-n-decyl adipate, di-n-octyl adipate, diisononyl adipate, n-octyl-n-decyl adipate, di-n-decyl adipate, di-2-ethylhexyl sebacate, di-2-ethylhexyl azelate, di-2-ethylhexyl maleate, O-acetyl tributyl citrate, di-2-ethylhexyl phthalate and the like. A mixture of two or more types of the above esters may also be used.

The resist composition of the present invention comprises, in addition to (D) the polyvalent carboxylic acid ester. (A) an alkali-soluble resin or a resin capable of becoming alkali-soluble as a binder component, and (B) an active compound that generates acid under exposure to radiation as a radiation-sensitive component, to utilize catalysis of the acid generated from the radiation-sensitive component in a radiation-exposed portion. In the chemical amplifying type positive resist, acid generated in the radlation-exposed portion diffuses during subsequent heat treatment (post exposure baking), deblocking protecting groups of the resin etc. and also re-producing acid to make the radiation-exposed portion alkali-soluble. The chemical amplifying type positive resist has two types. In one type, the binder resin is alkali-soluble, and the resist comprises, in addition to the binder component and a radiation-sensitive component, a dissolution inhibitor having a protecting group capable of being deblocked due to the action of an acid. The dissolution inhibitor itself has a capability of suppressing dissolution of the alkali-soluble binder resin, but becomes alkali-soluble once the protecting group is deblocked due to the action of an acid. In the other type, the binder resin has a protecting group capable of being deblocked due to the action of an acid. The binder resin itself is insoluble or hardly soluble in alkali, but becomes alkali-soluble once the protecting group is deblocked due to the action of an acid.

In the chemical amplifying type positive resist, as the binder resin that is alkali-soluble itself, an alkali-soluble resin having a phenol skeleton, an alkali-soluble resin having a (meta)acrylic acid ester skeleton with an alicyclic ring and a carboxyl group on the alcohol side of the ester or the like may be used. Specific examples of such a resin include: polyvinyl phenol resins; polyisopropenylphenol resins; resins in which the hydroxyl group of such polyvinylphenol resins and polyisopropenylphenol resins has been partly alkyletherified; copolymer resins of vinylphenol or isopropenylphenol and other polymeric unsaturated compounds; polymers of alicyclic esters of (meta)acrylic acid having a carboxyl group at the alicyclic ring; and copolymer resins of alicyclic esters of (meta)acrylic acid and (meta)acrylic acid.

When an alkali-soluble resin as described above itself is used as the binder component, a dissolution inhibitor is used. The dissolution inhibitor may be a phenolic compound of which a phenolic hydroxyl group is protected with a group having dissolution Inhibiting capability against an alkaline developer but debloaked due to the action of an acid. An example of the group deblocked due to the action of an acid is a tert-butoxycarbonyl group, which is to substitute for hydrogen of the phenolic hydroxyl group. Examples of the dissolution inhibitor include 2,2-bis(4-tert-butoxycarbonyloxyphenyl)propane, bis(4-tert-butoxycarbonyloxyphenyl)sulfone and 3,5-bis(4-tert-butoxycarbonyloxyphenyl)-1,1,3-trimethylindan.

When a resin that is insoluble or hardly soluble itself in alkali but becomes alkali-soluble once the protecting group is deblocked due to the action of an acid is used as the binder component, the binder resin may be a resin obtainable by introducing a protecting group capable of being deblocked due to the action of an acid in an alkali-soluble resin, such as a resin having a phenol skeleton or a resin having a (meta)acrylic acid skeleton as described above.

Examples of the group having dissolution inhibiting capability against an alkali developer but unstable against acid include; tert-butyl; groups with quaternary carbon bound to oxygen atoms, such as, tert-butoxyczarbonyl, and tert-butoxy carbonylmethyl: acetal groups such as tetrahydro-2-pyranyl, tetrahydro-2-furyl, 1-ethoxyethyl, 1-(2-methylpropoxy)ethyl, 1-(2-methoxyethoxy)ethyl, 1-(2-acetoxyethoxy)ethyl, 1-[2-(1-adamantyloxy)ethoxy]ethyl and 1-[2-(1-adamantanecarbonyloxy)ethoxy]ethyl; and residues of non-aromatic cyclic compounds such as 3-oxocyclohexyl, 4-methyltetrahydro-2-pyrrone-4-yl(derived from mevalonic lactone), 2-methyl-2-adamantyl and 2-ethyl-2-adamantyl.

The group as described above substitutes for hydrogen of the phenolic hydroxyl group or carboxyl group. The protecting group can be introduced into the alkali-soluble resin having a phenolic hydroxyl group or a carboxyl group by known reaction for introduction of a protecting group. Alternatively, the resin may be obtained by copolymerization using an unsaturated compound having such a group as a monomer.

The component (A) according to the present invention preferably has at least one type of polymerlzation unit selected from those derived from monomers having an adamantane group. For example, the component (A) has a polymerization unit derived from (meta)acrylic acid 2-methyl-2-adamantyl or (meta)acrylic acid 2-ethyl-2-adamantyl is preferred.

More preferably, as component (A) according to the present invention, a resin having a polymerization unit derived from hydroxystyrene and a polymerization unit derived from (meta)acrylic acid 2-methyl-2-adamantyl or (meta)acrylic acid 2-ethyl-2-adamrantyl is used.

The acid-generating agent (B), another component of the present invention, may be a substance which is decomposed to generate an acid by applying a radiation such as a light, an electron beam or the like on the substance itself or on a resist composition containing the substance.

Such acid generating agents, for example, include oniun salt compounds, organno-halogen compound of triazine type, sulfone compounds, compounds having diazomethanesulfonyl skeleton, sulfonate compounds, and the like, and onium salt compounds, organno-halogen compound of triazine type, sulfone compounds and sulfonate compounds are preferred.

Specific examples thereof include: diphenyliodonium trifluoromethanesulfonate,

4-methoxyphenylphenyliodonium hexafluoroantimonate,

4-mthoxyphenylphenyliodonium trifluoromethanesulfonate,

bis(4-tert-butylphenyl)iodonium tetrafluoroborate,

bis(4-tert-butylphenyl)iodonium hexafluorophosphate,

bis(4-tert-butylphenyl)iodonium hexafluoroantimonate,

bis(4-tert-butylphenyl)iodonium trifluoromethanesulfonate,

triphenylsulfonium hexafluorophosphate,

triphenylsulfonium hexafluoroantimonate,

triphenylsulfonium trifluoromethanesulfonate,

4-methoxyphenyldiphenylsulfonium hexafluoroantimonate,

4-methoxyphenyldiphenylsulfonium trifluoromethanesulfonate,

p-tolyldiphanylsulfonium trifluoromehtanesulfonate,

p-tolyldiphanylsulfonium perfluorobutanesulfonate,

p-tolyldiphenylsulfonium perfluorooctanesulfonate,

2,4,6-trimethylphenyldiphenylsulfonium trifluoromehtanesulfonate,

4-tert-butylphenyldiphenylsulfonium trifluoromethanesulfonate, trifluoromehtanesulfonate,

4-phenylthiophenyldiphenylsulfonium hexafluorophosphate,

4-phenylthiophenyldiphenylsulfonium hexafluoroantimonate,

1-(2-naphthoylmethyl)thiolanium hexafluoroantimonate,

1-(2-naphthoylmethyl)thiolanium trifluoromethanesulfonate,

4-hydroxy-1-naphthyldimethylsulfonium hexafluoroantimonate,

4-hydroxy-1-naphthyldimethylsulfonium trifluoromethanesulfonate,

cyclohexylmethyl(2-oxocyclohexyl)sulfonium trifluoromethanesulfonate,

cyclohexylmehtyl(2-oxocyolohexyl)sulfonium perfluorobutanesulfonate,

cyclohexylmethyl(2-oxocyclohexyl)sulfonium perfluorooctanesulfonate,

2-methyl-4,6-bis(trichloromethyl)-1,3,5-triazine,

2,4,6-tris(trichloromethyl)-1,3,5-triazine,

2-phenyl-4,6-bis(trichloromethyl)-1,3,5-triazine,

2-(4-chlorophenyl)-4,6-bis(trichloromethyl)-1,3,5-triazine,

2-(4-methoxyphenyl)-4,6-bis(trichloromethyl)-1,3,5-triazine,

2-(4-methoxy-1-naphthyl)-4,6-bis(trichloromethyl)-1,3,5-triazine,

2-(benzo[d][1,3]dioxolane-5-yl)-4,6-bis(trichloromethyl)-1,3,5-triazine,

2-(4-methoxystyryl)-4,6-bis(trichloromethyl)-1,3,5-triazine,

2-(3,4,5-trimethoxystyryl)-4,6-bis(trichloromethyl)-1,3,5-triazine,

2-(3,4-dimethoxystyryl)-4,6-bis(trichloromethyl)-1,3,5-triazine,

2-(2,4-dimethoxystyryl)-4,6-bis(trichloromethyl)-1,3,5-triazine,

2-(2-methoxystyryl)-4,6-bis(trichloromehtyl)-1,3,5-triazine,

2-(4-butoxystyryl)-4,6-bis(trichloromethyl)-1,3,5-triazine,

2-(4-pentyloxystyryl)-4,6-bis(trichloromethyl)-1,3,5-triazine,

diphenyl disulfone,

di-p-tolyl disulfone,

bis(phenylsulfonyl)diazomethane,

bis(4-chlorophenylsulfonyl)diazomethane,

bis(p-tolylsulfonyl)diazomethane,

bis(4-tert-butylphenylsulfonyl)diazomethane,

bis(2,4-xylylsulfonyl)diazomethane,

bis(cyclohexylsulfonyl)diazomethane,

(benzoyl)(phenylsulfonyl)diazomethane,

1-benzoyl-1-phenylmethyl p-toluenesulfonate (so-called benzointosylate),

2-benzoyl-2-hydroxy-2-phenylethyl p-toluenesulfonate (so-called α-methylolbenzointosylate),

1,2,3-benzenetriyl trimethanesulfonate,

2,6-dinitrobenzyl p-toluenesulfonate,

2-nitrobenzyl p-toluenesulfonate,

4-nitrobenzyl p-toluenesulfonate,

N-(phenylsulfonyloxy)succinimide,

N-(trifluoromethylsulfonyloxy)succinimide,

N-(trifluoromethylsulfonyloxy)phthalimide,

N-(trifluoromethylsulfonyloxy)-5-norbornene-2,3-dicarboxyimide,

N-(trifluoromethylsulfonyloxy)naphthalimide,

N-(10-camphorsulfonyloxy)naphthalimide, and the like.

The chemical amplifying type resist composition of the present invention further comprises (C) basic compounds, especially basic nitrogen-containing organic compounds such as amines quenchers. Concrete examples of the basic compounds to be used as quenchers include the ones represented by the following formulae;

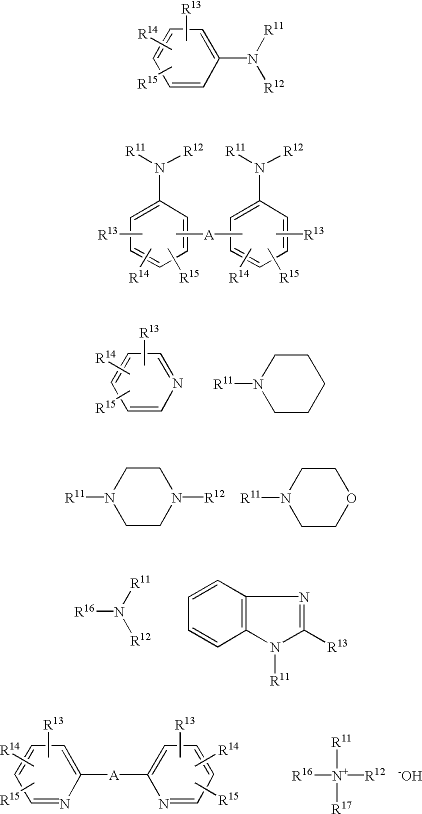

wherein R¹¹, R¹² and R¹⁷ represent, independently each other, hydrogen, cycloalkyl, aryl or alkyl which may be optionally substituted with a hydroxyl, amino which may be optionally substitiuted with alkyl having 1 to 6 carbon atoms, or alkoxy having 1 to 6 carbon atoms; R¹³, R¹⁴ and R¹⁵, which are same or different from each other, represent hydrogen, cycloalkyl, aryl, alkoxy or alkyl which may be optionally substituted with a hydroxyl, amino which may be optionally substitiuted with alkyl having 1 to 6 carbon atoms, or alkoxy having 1 to 6 carbon atoms; R¹⁶ represents cycloalkyl or alkyl which may be optionally substituted with a hydroxyl, amino which may be optionally substitiuted with alkyl having 1 to 6 carbon atoms, or alkoxy having 1 to 6 carbon atoms; A represents alkylene, carbonyl, imino, sulfide or disulfide. The alkyl represented by R¹¹ to R¹⁷ and alkoxy represented by R¹³ to R¹⁵ may have about 1 to 6 carbon atoms. The cycloalkyl represented by R¹¹ to R¹⁷ may have about 5 to 10 carbon atoms and the aryl represented by R¹¹ to R¹⁵ and R¹⁷ may have about 6 to 10 carbon atoms. The alkylene represented by A may have about 1 to 6 carbon atoms and may be straight-chained or branched.

The resist composition of the present invention preferably contains the acid-generating agent in an amount of 0.1 to 20 parts by weight and a polyvalent carboxylic acid ester in an amount of 0.1 to 10 parts by weight, more preferably 0.2 to 3 parts by weight, per 100 parts by weight of the resin becoming alkali-soluble due to the action of an acid.

It is also preferred that the basic compound contained in an amount of 0.001 to 1 parts by weight, more preferably 0.01 to 1 parts by weight, per 100 parts by weight of the resin becoming alkali-soluble due to the action of an acid.

The composition may also contain, if required, a small amount of various additives such as sensitizers, dissolution inhibitors, resins other than the above resin, surfactants, stabilizers, and dyes so far as the objects of the present invention is not impaired.

The resist composition of the present invention generally becomes a resist solution in the state in which the above-described components are dissolved in a solvent to be applied on a substrate such as a silicon wafer. The solvent herein used may be one which dissolves each component, has an appropriate drying rate, and provides a uniform and smooth coating after evaporation of the solvent, and can be one which is generally used in this field.

Examples thereof include glycol ether esters such as ethylcellosolve acetate, methylcellosolve acetate, and propylene glycol monomethyl ether acetate; esters such as ethyl lactate, butyl acetate, amyl acetate, and ethyl pyruvate; ketones such as acetone, methyl isobutyl ketone, 2-heptanone, and cyclohexanone; and cyclic esters such as γ-butyrolactone. These solvents can be used alone or in combination of two or more thereof.

The resist film applied on a substrate, and dried is subjected to an exposure treatment for patterning. Then, after a heat-treatment for promoting a protecting deblocking reaction, development by an alkali developer is conducted. The alkali developer herein used can be various kinds of alkaline aqueous solutions used in this field. In general, an aqueous solution of tetramethylammoniumhydroxide or (2-hydroxyethyl)trimethylammoniumhydroxide (so-called colline) is often used.

The present invention will be described in more detail by way of examples, which should not be construed as limiting the scope of the present invention. All “%” and parts for representing content or used amount in examples are by weight unless otherwise stated. The weight-average molecular weight (Mw) or degree of dispersion (Mw/Mn) is a value determined from gel permeation chromatography using polystyrene as a reference standard.

### SYNTHESIS EXAMPLE (1a)

### Synthesis of Copolymer of 2-ethyl-2-adamantyl methacrylate and p-acetoxystyrene (20:80)

Into a flask was charged 39.7 g (0.16 mol) of 2-ethyl-2-adamantyl methacrylate, 103.8 g (0.64 mol) of p-acetoxystyrene and 265 g of isopropanol and the atmosphere was purged with nitrogen. The resultant solution was heated to 75° C. Into this solution, 11.05 g (0.048 mol) of dimethyl 2,2′-azobis(2-methylproplonate) dissolved in 22.11 g of isopropanol was added dropwise. The mixture was kept for about 0.3 hours at 75° C. and for about 12 hours under reflux. Then, the mixture was diluted with acetone, and charged into methanol to precipitate a crystal which was removed by filtration. The crude crystal of the copolymer of 2-ethyl-2-adamantyl methacrylate and p-acetoxystyrene was obtained in an amount of 250 g.

### SYNTHESIS EXAMPLE (1b)

### Synthesis of Copolymer of 2-ethyl-2-adamantyl methacrylate and p-hydroxystyrene (20:80)

Into a flask was charged 250 g of the crude crystal of the copolymer of 2-ethyl-2-adamantyl methacrylate and p-acetoxystyrene (20:80) obtained in (1a), 10.3 g (0.084 mol) of 4-dimethylaminopyridine and 202 g methanol. The resultant solution was kept for 20 hours under reflux. After cooling, the solution was neutralized with 7.6 g (0.126 mol) of glacial acetic acid, and charged into water to precipitate a crystal which was removed by filtration. Then, the crystal was dissolved in acetone, and charged into water to precipitate a crystal which was removed by filtration. This operation was repeated three times in total, then, the resulted crystal was dried. The crystal of the copolymer of 2-ethyl-2-adamantyl methacrylate and p-hydroxystyrene was obtained in an amount of 95.9 g. The resin had a weight-average molecular weight of about 8600 and a degree of dispersion of 1.65 (GPC method: in terms of polystyrene), and revealed a copolymerization ratio of about 20:80 measured by anuclear magnetic resonance (¹³C-NMR) spectrometer. This resin is called Resin A.

### SYNTHESIS EXAMPLE (2a)

### Synthesis of Copolymer of 2-ethyl-2-adamantyl methacrylate and p-acetoxystyrene (30;70)

Into a flask was charged 59.6 g (0.24 mol) of 2-ethyl-2-adamantyl methacrylate, 90.8 g (0.56 mol) of p-acetoxystyrene and 279 g of isopropanol and the atmosphere was purged with nitrogen. Then, the solution was heated to 75° C. Into this solution, 11.05 g (0.048 mol) of dimethyl 2,2′-azobis(2-methylpropionate) dissolved in 22.11 g of isopropanol was added dropwise. The mixture was kept for about 0.3 hours at 75° C. and for about 12 hours under reflux, then, diluted with acetone, and charged into methanol to precipitate a crystal which was removed by filtration. The crude crystal of the copolymer of 2-ethyl-2-adamantyl methaorylate and p-acetoxystyrene was obtained in an amount of 250 g.

### SYNTHESIS EXAMPLE (2b)

### Synthesis of Copolymer of 2-ethyl-2-adamantyl methacrylate and p-hydroxystyrene (30:70)

Into a flask was charged 250 g of the crude crystal of the copolymer of 2-ethyl-2-adamantyl methacrylate and p-acetoxystyrene (30:70) obtained in (2a), 10.8 g (0.088 mol) of 4-dimethylaminopyridine and 239 g methanol. Then, the solution was kept for 20 hours under reflux. After cooling, the solution was neutralized with 8.0 g (0.133 mol) of glacial acetic acid, and charged into water to precipitate a crystal which was removed by filtration. Then, the crystal was dissolved in acetone, and charged Into water to precipitate a crystal which was removed by filtration. This operation was repeated three times in total, then, the resulted crystal was dried. The crystal of the copolymer of 2-ethyl-2-adamantyl methacrylate and p-hydroxystyrene was obtained in an amount of 102.8 g. The resin had a weight-average molecular weight of about S200 and a degree of dispersion of 1.68 (GPC method: in terms of polystyrene), and revealed a copolymerization ratio of about 30:70 measured by a nuclear magnetic resonance (¹³C-NMR) spectrometer. This resin is called Resin B.

### EXAMPLES AND COMPARATIVE EXAMPLE

Resin A and Resin B was mixed at a ratio of 1:1 to give a resin, and this resin was mixed with acid generating agents of the following formulae (III) and (IV), quencher and solvent in a formulation shown below to provide a solution. This solution was further filtrated through a fluorine resin filter having a pore diameter of 0.2 μm to prepare a resist solution.

| | |
|---|---|
| | (III) |
| 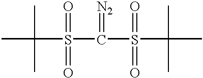 | |
| | (IV) |
| 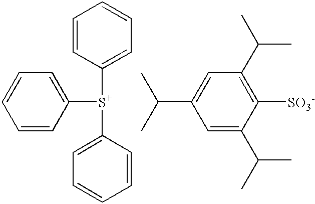 | |

| | | |
|---|---|---|
| Resin mixture | | 13.5 parts |
| Acid generating | acid generating agent | 0.45 parts |
| agent | (III) | |
| | acid generating agent | 0.45 parts |
| | (IV) | |
| Quencher | diisopropylaniline | 0.055 parts |
| Solvent | propylene glycol | 90 parts |
| | monomethyl ether | |
| | acetate | |

To this resist solution was added a polyvalent carboxylic acid ester shown in Table 1 in an amount shown in Table 1 as % by weight based on solid content of the resin.

TABLE 1

| Example No. | | Amount (*) |
|---|---|---|
| comparative 1 | di-n-alkyl adipate | 1.0 |
| comparative 2 | di-2-ethylhexyl adipate | 1.0 |
| comparative 3 | diisononyl adipate | 1.0 |
| comparative 4 | di-2-ethylhexyl sebacate | 1.0 |
| comparative 5 | di-2-ethylhexyl azelate | 1.0 |
| comparative 6 | O-acetyl tributyl citrate | 1.0 |
| comparative 7 | di-2-ethylhexyl maleate | 1.0 |
| comparative 8 | di-2-ethylhexyl phthalate | 1.0 |
| comparative 9 | di-2-alkyl adipate | 2.2 |
| Comparative | Not added | |
| example 1 | | |
| Comparative | Not added | |
| example 2 | | |

Di-n-alkyl adipate (Tokyo Kasei Kogyo Co., Ltd) is a mixture of compounds represented by formula (V) below.

R₁₈—O—CO—(CH₂)₄—CO—O—R₁₉ (V)

where R₁₈ and R₁₉ are independently alkyl groups having 6, 8, or 10 carbons.

### For Examples 1-8 and Comparative Example 1

On a silicon wafer, an anti-reflection film [“DTV-42” manufactured by Nissan Chemical Industries. Ltd. ] was applied under pre-bake conditions of 215° C. and 60 seconds to give a thickness of 0.06 μm. Then, each resist solution was spin-coated on this, followed by pre-baking on a proximity hot plate under conditions of 110° C. and 60 seconds to form a resist film having a thickness of 0.42 μm for Examples 1-8 and Comparative example 1 or a thickness of 0.35 μm for Examples 9 and Comparative example 2.

For Examples 1-8 and Comparative example 1, a wafer carrying thus formed resist film was exposed using a KrF excimer stepper [“NSR S203B” manufactured by Nikon Corp., NA=0.68, σ=0.85, ⅔ annular illumination exposure] via masks having various forms and dimensions.

For Example 9 and Comparative example 2, a wafer carrying thus formed resist film was exposed using an electron beam direct drawing exposure apparatus (HL-8000, manufactured by HITACHI, acceleration voltage: 500 kV).

Then, PEB was conducted under conditions of 130° C. and 60 seconds on a hot plate, further, paddle development was conducted for 60 seconds with a 2.38% tetramethyl ammonium hydroxide aqueous solution. Patterns after development were observed by a scanning electron microscope, and sensitivity, resolution and presence of scum were checked as described below. Results are shown in Table 2.

Effective sensitivity. This was indicated by exposure amount at which 0.15 μm line and space pattern was 1:1.

Resolution: This was indicated by the minimum dimension of line and space pattern separating at exposure of effective sensitivity.

TABLE 2

| | | |
|---|---|---|
| Example No. | Effective sensitivity | Resolution |

| | | |
|---|---|---|
| comparative 1 | 44 mJ/cm² | 0.12 |
| comparative 2 | 41 mJ/cm² | 0.12 |
| comparative 3 | 41 mJ/cm² | 0.12 |
| comparative 4 | 40 mJ/cm² | 0.12 |
| comparative 5 | 40 mJ/cm² | 0.12 |
| comparative 6 | 40 mJ/cm² | 0.12 |
| comparative 7 | 41 mJ/cm² | 0.12 |
| comparative 8 | 42 mJ/cm² | 0.12 |
| comparative 9 | 34 μC/cm² | 0.05 |
| Comparative | 40 mJ/cm² | 0.13 |
| example 1 | | |
| Comparative | 34 μC/cm² | 0.13 |
| example 2 | | |

The chemical amplifying positive resist composition of the present invention exhibits higher resolution without impairing resist performance such as application ability and sensitivity. Therefore, the composition is suitable for lithography using radiation such as KrF and ArF excimer laser light and electron beams. By this application, fine resist patterns can be formed with high precision.

What is claimed is:

1. A chemical amplifying type positive resist composition comprising (A) a resin becoming alkali-soluble due to the action of an acid, (B) an acid generating agent, (C) a basic compound, and (D) a polyvalent carboxylic acid ester.

2. The chemical amplifying type positive resist composition according to claim 1, wherein the component (A) has at least one type of polymerization unit selected from those derived from monomers having an admantane group.

3. The chemical amplifying type positive resist composition according to claim 1, wherein the component (A) has a polymerization unit derived from (meta)acrylic acid 2-methyl-2-adamantyl or (meta)acrylic acid 2-ethyl-2-adamantyl.

4. The chemical amplifying type positive resist composition according to claim 1, wherein a resin having a polymerization unit derived from hydroxystyrene and a polymerization unit derived from (meta)acrylic acid 2-methyl-2-adamantyl or (meta)acrylic acid 2-ethyl-2-adamantyl is used as the component (A).

5. The chemical amplifying type positive resist composition according to claim 1, wherein the component (B) is selected from onium salt compounds, organno-halogen compound of triazine type, sulfone compounds and sulfonate compounds.

6. The chemical amplifying type positive resist composition according to claim 1, wherein the component (C) is selected from basic nitrogen-containing organic compounds.

7. The chemical amplifying type positive resist composition according to claim 1, wherein the component (C) is selected from amines.

8. The chemical amplifying type positive resist composition according to claim 1, wherein the component (C) is selected from adipic acid esters, sebacic acid esters, azelaic acid esters, maleic acid esters, citric acid esters and phthalic acid esters.

9. The chemical amplifying type positive resist composition according to claim 1, wherein the component (C) is selected from di-n-hexyl adipate, n-hexyl-n-octyl adipate, di-2-ethylhexyl adipate, n-hexyl-n-decyl adipate, di-n-octyl adipate, diisononyl adipate, n-octyl-n-decyl adipate, di-n-decyl adipate, di-2-ethylhexyl sebacate, di-2-ethylhexyl azelate, di-2-ethylhexyl maleate, O-acetyl tributyl citrate and di-2-ethylhexyl phthalate.
